(19) United States
(12) Patent Application Publication
(10) Pub. No.: US 2021/0167102 A1
(43) Pub. Date: Jun. 3, 2021

(54) ULTRAVIOLET LIGHT IMAGE SENSOR

(71) Applicant: SHENZHEN XPECTVISION TECHNOLOGY CO., LTD., Shenzhen (CN)

(72) Inventors: Peiyan CAO, Shenzhen (CN); Yurun LIU, Shenzhen (CN)

(21) Appl. No.: 17/176,687

(22) Filed: Feb. 16, 2021

Related U.S. Application Data
(63) Continuation of application No. PCT/CN2018/104596, filed on Sep. 7, 2018.

(51) Int. Cl. H01L 27/146; H01L 31/107

(52) U.S. Cl. CPC H01L 27/1461; H01L 31/107; H01L 27/14643; H01L 27/1462

(57) ABSTRACT

Disclosed herein is an apparatus, comprising: an array of avalanche photodiodes (APDs) configured to detect UV light; a bandpass optical filter that blocks visible light and passes UV light incident on the array of APDs.

### TECHNICAL FIELD

The disclosure herein relates to an ultraviolet (UV) light image sensor, particularly relates to a UV light image sensor comprising avalanche photodiodes (APD).

### BACKGROUND

An image sensor or imaging sensor is a sensor that can detect a spatial intensity distribution of a radiation. An image sensor usually represents the detected image by electrical signals. Image sensors based on semiconductor devices may be classified into several types, including semiconductor charge-coupled devices (CCD), complementary metal-oxide-semiconductor (CMOS), N-type metal-oxide-semiconductor (NMOS). A CMOS image sensor is a type of active pixel sensor made using the CMOS semiconductor process. Light incident on a pixel in the CMOS image sensor is converted into an electric voltage. The electric voltage is digitized into a discrete value that represents the intensity of the light incident on that pixel. An active-pixel sensor (APS) is an image sensor that includes pixels with a photodetector and an active amplifier. A CCD image sensor includes a capacitor in a pixel. When light incidents on the pixel, the light generates electrical charges and the charges are stored on the capacitor. The stored charges are converted to an electric voltage and the electrical voltage is digitized into a discrete value that represents the intensity of the light incident on that pixel.

UV light is an electromagnetic radiation with a wavelength from 10 nm to 400 nm, between X-rays and visible light. UV image sensors may be useful in a wide range of applications, including fire detection, industrial manufacturing, biochemical research, light sources, and environmental and structural health monitoring.

### SUMMARY

Disclosed herein is an apparatus, comprising: an array of avalanche photodiodes (APDs) configured to detect UV light; a bandpass optical filter that blocks visible light and passes UV light incident on the array of APDs.

According to an embodiment, each of the APDs comprises an absorption region and an amplification region.

According to an embodiment, the absorption region is configured to generate charge carriers from a UV photon absorbed by the absorption region.

According to an embodiment, the amplification region comprises a junction with an electric field in the junction.

According to an embodiment, the electric field is at a value sufficient to cause an avalanche of charge carriers entering the amplification region, but not sufficient to make the avalanche self-sustaining.

According to an embodiment, the junctions of the APDs are discrete.

According to an embodiment, the absorption region has an absorptance of at least 80% for UV light.

According to an embodiment, the absorption region has a thickness of 10 microns or above.

According to an embodiment, the absorption region comprises silicon.

According to an embodiment, an electric field in the absorption region is not high enough to cause avalanche effect in the absorption region.

According to an embodiment, the absorption region is an intrinsic semiconductor or a semiconductor with a doping level less than 10¹² dopants/cm³.

According to an embodiment, the absorption regions of at least some of the APDs are joined together.

According to an embodiment, the apparatus further comprises two amplification regions on opposite sides of the absorption region.

According to an embodiment, the amplification regions of the APDs are discrete.

According to an embodiment, the junction is a p-n junction or a heterojunction.

According to an embodiment, the junction comprises a first layer and a second layer, wherein the first layer is a doped semiconductor and the second layer is a heavily doped semiconductor.

According to an embodiment, the first layer has a doping level of 10¹³ to 10¹⁷ dopants/cm³.

According to an embodiment, the first layers of at least some of the APDs are joined together.

According to an embodiment, the apparatus further comprises electric contacts respectively in electrical contact with the second layers of the APDs.

According to an embodiment, the apparatus further comprises a passivation material configured to passivate a surface of the absorption region.

According to an embodiment, the apparatus further comprises a common electrode electrically connected to the absorption region.

According to an embodiment, the junction is separated from a junction of a neighbor junction by a material of the absorption region, a material of the first or second layer, an insulator material, or a guard ring of a doped semiconductor.

According to an embodiment, the junction further comprises a third layer sandwiched between the first and second layers; wherein the third layer comprises an intrinsic semiconductor.

Disclosed herein is a system comprising an apparatus described above, wherein the system is configured to scan along a high voltage transmission line, to capture images of the high voltage transmission line using the apparatus, and to detect a location of damage on the high voltage transmission line based on the images.

The system may further comprise an unmanned aerial vehicle (UAV), wherein the apparatus is mounted to the UAV.

### BRIEF DESCRIPTION OF FIGURES

FIG. 1 schematically shows a UV image sensor, according to an embodiment.

FIG. 2 schematically shows electric currents in an avalanche photodiode (APD) as functions of an intensity of UV light incident on the APD, according to an embodiment.

FIG. 3A, FIG. 3B and FIG. 3C schematically show the operation of the APD, according to an embodiment.

FIG. 4A-FIG. 4D each schematically shows a cross section of a portion of an APD layer of a UV image sensor, according to an embodiment.

FIG. 5A and FIG. 5B each schematically shows a system comprising the UV image sensor described herein, for corona discharge detection for high voltage transmission lines.

### DETAILED DESCRIPTION

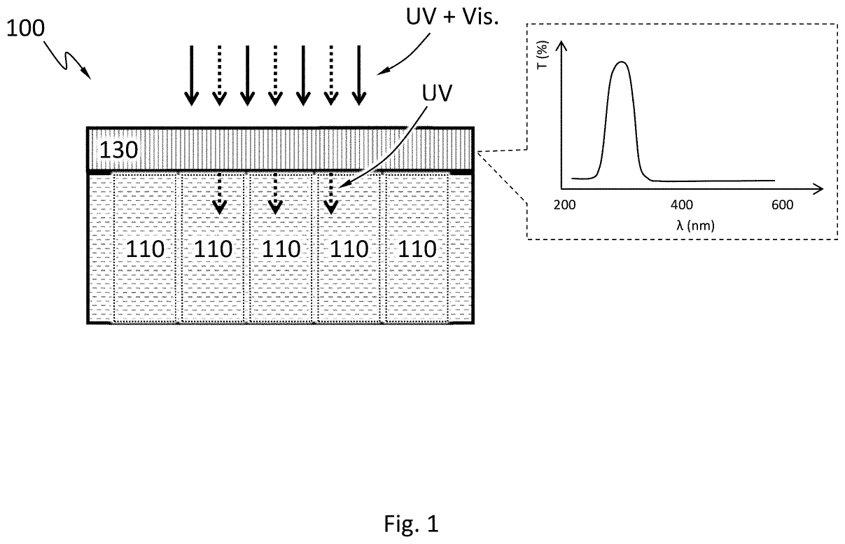

FIG. 1 schematically shows a UV image sensor 100, according to an embodiment. The UV image sensor 100 has an array of avalanche photodiodes (APDs) 110 and a bandpass optical filter 130. The APDs 110 may detect UV light. The bandpass optical filter 130 blocks visible light and passes UV light. The bandpass optical filter 130 does not necessarily passes all UV light. Instead, the bandpass optical filter 130 may pass UV light of certain wavelengths. For example, the bandpass optical filter 130 may pass UV light with a wavelength between 250 nm and 320 nm and block UV light of other wavelengths and visible light. The bandpass optical filter 130 may also block infrared light. The bandpass optical filter 130 may include crystalline alkali metals such as nickel sulfate hexahydrate (NSH), potassium nickel sulfate hexahydrate (KNSH), cesium nickel sulfate hexahydrate (CNSH), or a combination thereof. The bandpass optical filter 130 may have a stack structure of multiple layers of dielectric materials, or a metal nanometer-scale square grid structure.

An APD (e.g., one of the APDs 110) is a photodiode that uses the avalanche effect to generate an electric current upon exposure to light. The avalanche effect is a chain process where free charge carriers in a material are strongly accelerated by an electric field, subsequently collide with atoms of the material, and eject additional charge carriers from the atoms by impact ionization. Impact ionization is a process by which one energetic charge carrier can lose energy by the creation of other charge carriers. For example, in a semiconductor, an electron (or hole) with enough kinetic energy can free a bound electron from its bound state (e.g., excite the electron from the valance band to the conduction band).

An APD (e.g., one of the APDs 110) may work in the Geiger mode or the linear mode. When the APD works in the Geiger mode, it may be called a single-photon avalanche diode (SPAD) (also called a Geiger-mode APD or G-APD). A SPAD is an APD working under a reverse bias above the breakdown voltage. Here the word “above” means that absolute value of the reverse bias is greater than the absolute value of the breakdown voltage. A SPAD may be used to detect low intensity light (e.g., down to a single photon) and to signal the arrival times of the photons with a jitter of a few tens of picoseconds. A SPAD may be in a form of a p-n junction under a reverse bias (i.e., the p-type region of the p-n junction is biased at a lower electric potential than the n-type region) above the breakdown voltage of the p-n junction. The breakdown voltage of a p-n junction is a reverse bias, above which exponential increase in the electric current in the p-n junction occurs. An APD working at a reverse bias below the breakdown voltage is operating in the linear mode because the electric current in the APD is proportional to the intensity of the light incident on the APD.

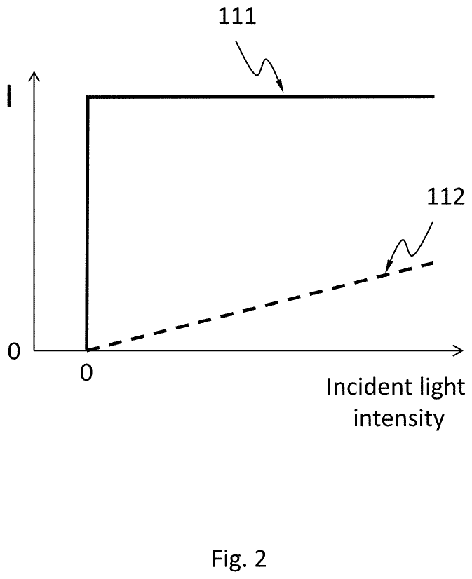

FIG. 2 schematically shows electric currents in an APD (e.g., one of the APDs 110) as functions of an intensity of light incident on the APD, according to an embodiment. The APD may work in the Geiger mode or the linear mode. A function 112 is the function of intensity of light incident on the APD when the APD is in the linear mode, and a function 111 is the function of the intensity of light incident on the APD when the APD is in the Geiger mode. In the Geiger mode, the current shows a very sharp increase with the intensity of the light and then saturation. In the linear mode, the current is essentially proportional to the intensity of the light.

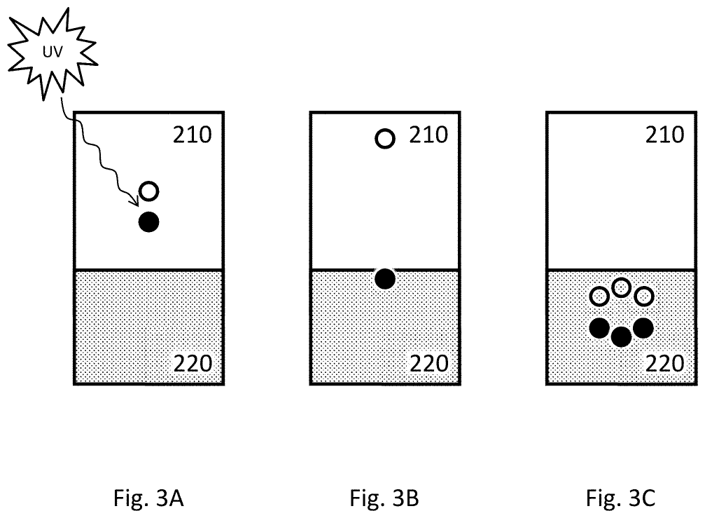

FIG. 3A, FIG. 3B and FIG. 3C schematically show the operation of an APD (e.g., one of the APDs 110), according to an embodiment. FIG. 3A shows that when a photon (e.g., a UV photon) is absorbed by an absorption region 210 of the APD, multiple electron-hole pairs maybe generated. The absorption region 210 has a sufficient thickness and thus a sufficient absorptance (e.g., >80% or >90%) for the photon. For UV photons, the absorption region 210 may be a layer of silicon or another suitable semiconductor material with a sufficient thickness (e.g., 10 microns or above). The electric field in the absorption region 210 is not high enough to cause the avalanche effect in the absorption region 210. FIG. 3B shows that the electrons and holes drift in opposite directions in the absorption region 210. FIG. 3C shows that the avalanche effect occurs in an amplification region 220 of the APD when the electrons (or the holes) enter that amplification region 220, thereby generating more electrons and holes. The electric field in the amplification region 220 is high enough to cause an avalanche of charge carriers entering the amplification region 220 but may or may not be high enough to make the avalanche effect self-sustaining. A self-sustaining avalanche is an avalanche that persists after the external triggers disappear, such as photons incident on the APD or charge carriers drifted into the APD. The electric field in the amplification region 220 may be a result of a doping profile in the amplification region 220. For example, the amplification region 220 may include a p-n junction or a heterojunction that has an electric field in its depletion zone. The threshold electric field for the avalanche effect (i.e., the electric field above which the avalanche effect occurs and below which the avalanche effect does not occur) is a property of the material of the amplification region 220. The amplification region 220 may be on one side or two opposite sides of the absorption region 210.

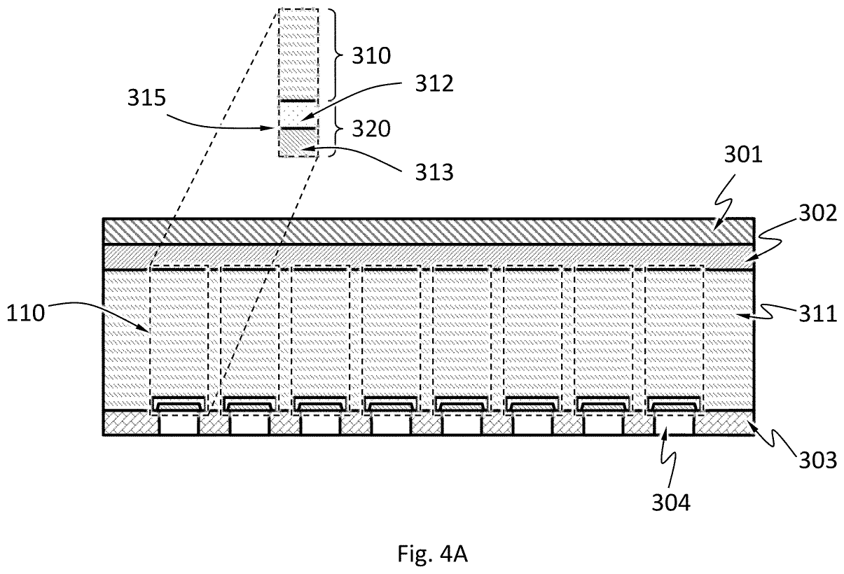

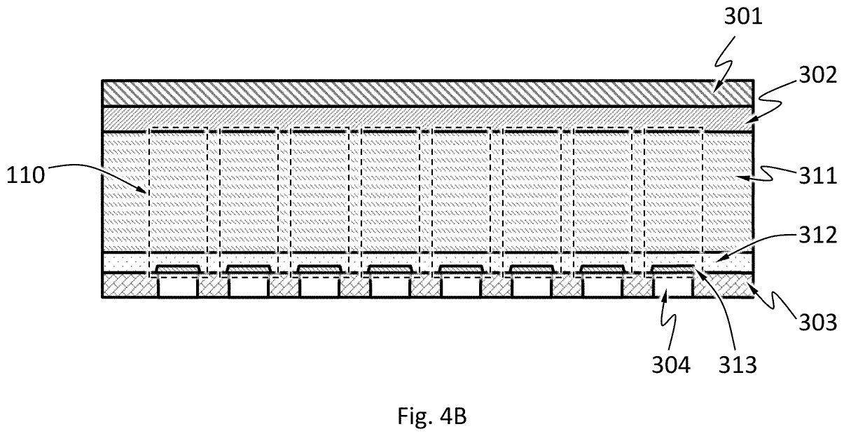

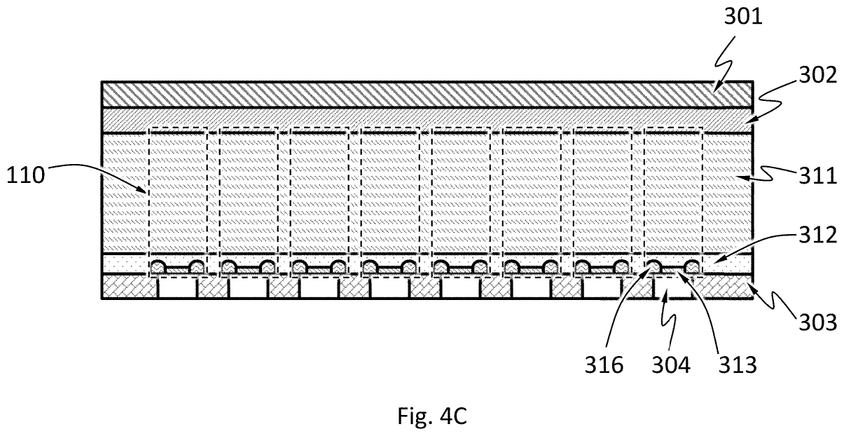

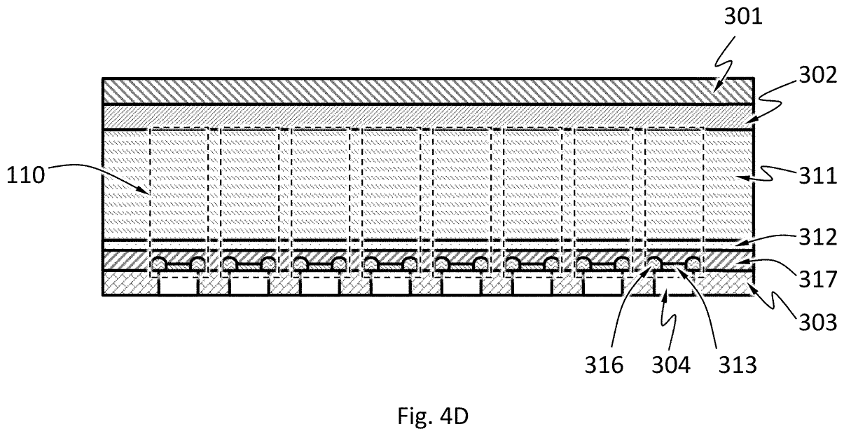

FIG. 4A schematically shows a cross section of the APDs 110 of the UV image sensor 100, according to an embodiment. Each of the APDs 110 may have an absorption region 310 and an amplification region 320 as the example shown in FIG. 3A, FIG. 3B and FIG. 3C. At least some, or all, of the APDs 110 in the UV image sensor 100 may have their absorption regions 310 joined together. Namely, the UV image sensor 100 may have joined absorption regions 310 in a form of an absorption layer 311 that is shared among at least some or all of the APDs 110. The amplification regions 320 of the APDs 110 are discrete regions. Namely the amplification regions 320 of the APDs 110 are not joined together. In an embodiment, the absorption layer 311 may be in form of a semiconductor wafer such as a silicon wafer. The absorption regions 310 may be an intrinsic semiconductor or very lightly doped semiconductor (e.g., <10¹² dopants/cm³, <10¹¹ dopants/cm³, <10¹⁰ dopants/cm³, <10⁹ dopants/cm³), with a sufficient thickness and thus a sufficient absorptance (e.g., >80% or >90%) for incident photons of interest (e.g., UV photons). The amplification regions 320 may have a junction 315 formed by at least two layers 312 and 313. The junction 315 may be a heterojunction of a p-n junction. In an embodiment, the layer 312 is a p-type semiconductor (e.g., silicon) and the layer 313 is a heavily doped n-type layer (e.g., silicon). The phrase “heavily doped” is not a term of degree. A heavily doped semiconductor has its electrical conductivity comparable to metals and exhibits essentially linear positive thermal coefficient. In a heavily doped semiconductor, the dopant energy levels are merged into an energy band. A heavily doped semiconductor is also called degenerate semiconductor. The layer 312 may have a doping level of 10¹³ to 10¹⁷ dopants/cm³. The layer 313 may have a doping level of 10¹⁸ dopants/cm³ or above. The layers 312 and 313 may be formed by epitaxy growth, dopant implantation or dopant diffusion. The band structures and doping levels of the layers 312 and 313 can be selected such that the depletion zone electric field of the junction 315 is greater than the threshold electric field for the avalanche effect for electrons (or for holes) in the materials of the layers 312 and 313, but is not too high to cause self-sustaining avalanche. Namely, the depletion zone electric field of the junction 315 should cause avalanche when there are incident photons in the absorption region 310 but the avalanche should cease without further incident photons in the absorption region 310.

The UV image sensor 100 may further include electric contacts 304 respectively in electrical contact with the layer 313 of the APDs 110. The electric contacts 304 are configured to collect electric current flowing through the APDs 110.

The UV image sensor 100 may further include a passivation material 303 configured to passivate surfaces of the absorption regions 310 and the layer 313 of the APDs 110 to reduce recombination at these surfaces.

The UV image sensor 100 may further include a heavily doped layer 302 disposed on the absorption regions 310 opposite to the amplification region 320, and a common electrode 301 on the heavily doped layer 302. The common electrode 301 of at least some or all of the APDs 110 may be joined together. The heavily doped layer 302 of at least some or all of the APDs 110 may be joined together.

When a UV photon passes the bandpass optical filter 130 and incidents on the APDs 110, it may be absorbed by the absorption region 310 of one of the APDs 110, and charge carriers may be generated in the absorption region 310 as a result. One type (electrons or holes) of the charge carriers drift toward the amplification region 320 of that one APD. When the charge carriers enter the amplification region 320, the avalanche effect occurs and causes amplification of the charge carriers. The amplified charge carriers can be collected through the electric contact 304 of that one APD, as an electric current. When that one APD is in the linear mode, the electric current is proportional to the number of incident photons in the absorption region 310 per unit time (i.e., proportional to the light intensity at that one APD). The electric currents at the APDs may be compiled to represent a spatial intensity distribution of light, i.e., an image. The amplified charge carriers may alternatively be collected through the electric contact 304 of that one APD, and the number of photons may be determined from the charge carriers (e.g., by using the temporal characteristics of the electric current).

The junctions 315 of the APDs 110 should be discrete, i.e., the junction 315 of one of the APDs should not be joined with the junction 315 of another one of the APDs. Charge carriers amplified at one of the junctions 315 of the APDs 110 should not be shared with another of the junctions 315. The junction 315 of one of the APDs may be separated from the junction 315 of the neighboring APDs by the material of the absorption region wrapping around the junction, by the material of the layer 312 or 313 wrapping around the junction, by an insulator material wrapping around the junction, or by a guard ring of a doped semiconductor. As shown in FIG. 4A, the layer 312 of each of the APDs 110 may be discrete, i.e., not joined with the layer 312 of another one of the APDs; the layer 313 of each of the APDs 110 may be discrete, i.e., not joined with the layer 313 of another one of the APDs. FIG. 4B shows a variant of the UV image sensor 100, where the layers 312 of some or all of the APDs are joined together. FIG. 4C shows a variant of the UV image sensor 100, where the junction 315 is surrounded by a guard ring 316. The guard ring 316 may be an insulator material or a doped semiconductor. For example, when the layer 313 is heavily doped n-type semiconductor, the guard ring 316 may be n-type semiconductor of the same material as the layer 313 but not heavily doped. The guard ring 316 may be present in the UV image sensor 100 shown in FIG. 4A or FIG. 4B. FIG. 4D shows a variant of the UV image sensor 100, where the junction 315 has an intrinsic semiconductor layer 317 sandwiched between the layer 312 and 313. The intrinsic semiconductor layer 317 in each of the APDs 110 may be discrete, i.e., not joined with other intrinsic semiconductor layer 317 of another APD. The intrinsic semiconductor layers 317 of some or all of the APDs 110 may be joined together.

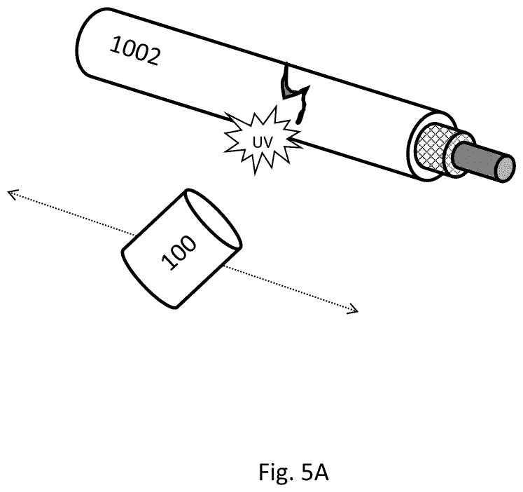

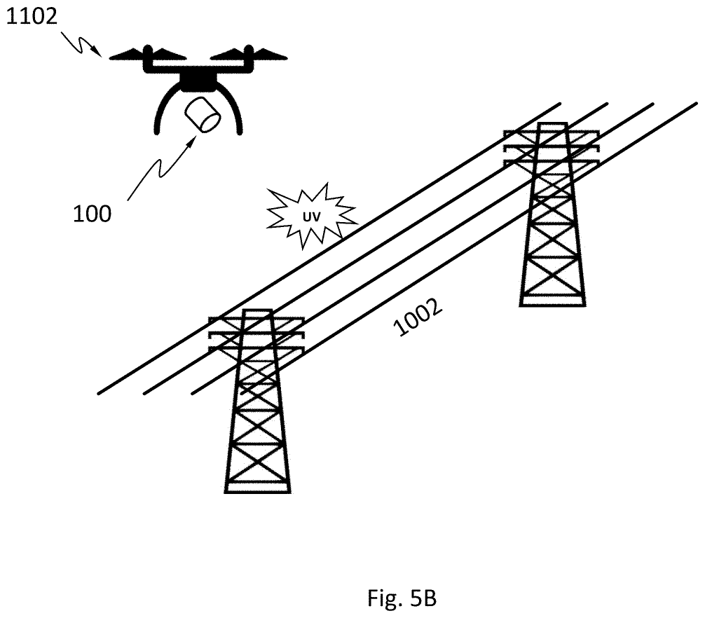

FIG. 5A schematically shows a system comprising the UV image sensor 100. The system may scan along a high voltage transmission line 1002, capture images of the high voltage transmission line 1002 with UV light using the UV image sensor 100, and detect locations of damages on the high voltage transmission line 1002. UV light may be emitted from the damages due to corona discharge. The system may include an unmanned aerial vehicle (UAV) 1102 with the UV image sensor 100 mounted thereto, as schematically shown FIG. 5B. The UAV may fly along the high voltage transmission line 1002.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

What is claimed is:

1. An apparatus, comprising:
an array of avalanche photodiodes (APDs) configured to detect UV light;
a bandpass optical filter that blocks visible light and passes UV light incident on the array of APDs.

2. The apparatus of claim 1, wherein each of the APDs comprises an absorption region and an amplification region.

3. The apparatus of claim 2, wherein the absorption region is configured to generate charge carriers from a UV photon absorbed by the absorption region.

4. The apparatus of claim 2, wherein the amplification region comprises a junction with an electric field in the junction.

5. The apparatus of claim 4, wherein the electric field is at a value sufficient to cause an avalanche of charge carriers entering the amplification region, but not sufficient to make the avalanche self-sustaining.

6. The apparatus of claim 4, wherein the junctions of the APDs are discrete.

7. The apparatus of claim 2, wherein the absorption region has an absorptance of at least 80% for UV light.

8. The apparatus of claim 2, wherein the absorption region has a thickness of 10 microns or above.

9. The apparatus of claim 2, wherein the absorption region comprises silicon.

10. The apparatus of claim 2, wherein an electric field in the absorption region is not high enough to cause avalanche effect in the absorption region.

11. The apparatus of claim 2, wherein the absorption region is an intrinsic semiconductor or a semiconductor with a doping level less than 10¹² dopants/cm³.

12. The apparatus of claim 2, wherein the absorption regions of at least some of the APDs are joined together.

13. The apparatus of claim 2, further comprising two amplification regions on opposite sides of the absorption region.

14. The apparatus of claim 2, wherein the amplification regions of the APDs are discrete.

15. The apparatus of claim 4, wherein the junction is a p-n junction or a heterojunction.

16. The apparatus of claim 4, wherein the junction comprises a first layer and a second layer, wherein the first layer is a doped semiconductor and the second layer is a heavily doped semiconductor.

17. The apparatus of claim 16, wherein the first layer has a doping level of 10¹³ to 10¹⁷ dopants/cm³.

18. The apparatus of claim 16, wherein the first layers of at least some of the APDs are joined together.

19. The apparatus of claim 16, further comprising electric contacts respectively in electrical contact with the second layers of the APDs.

20. The apparatus of claim 2, further comprising a passivation material configured to passivate a surface of the absorption region.

21. The apparatus of claim 2, further comprising a common electrode electrically connected to the absorption region.

22. The apparatus of claim 16, wherein the junction is separated from a junction of a neighbor junction by a material of the absorption region, a material of the first or second layer, an insulator material, or a guard ring of a doped semiconductor.

23. The apparatus of claim 16, wherein the junction further comprises a third layer sandwiched between the first and second layers; wherein the third layer comprises an intrinsic semiconductor.

24. A system comprising the apparatus of claim 1, wherein the system is configured to scan along a high voltage transmission line, to capture images of the high voltage transmission line using the apparatus, and to detect a location of damage on the high voltage transmission line based on the images.

25. The system of claim 24, further comprising an unmanned aerial vehicle (UAV), wherein the apparatus is mounted to the UAV.
